(19) United States
(12) Patent Application Publication
(10) Pub. No.: US 2026/0073956 A1
(43) Pub. Date: Mar. 12, 2026

(54) SEMICONDUCTOR DEVICE

(71) Applicant: Samsung Electronics Co., Ltd., Suwon-si (KR)

(72) Inventors: Haewook Jeong, Suwon-si (KR); Hoyoun Kim, Suwon-si (KR); Keonhee Park, Suwon-si (KR); Yeonjin Lee, Suwon-si (KR)

(21) Appl. No.: 19/292,358

(22) Filed: Aug. 6, 2025

(30) Foreign Application Priority Data
Sep. 10, 2024 (KR) 10-2024-0123416

(51) Int. Cl. G11C 5/06; G11C 11/22; H10B 53/40

(52) U.S. Cl. CPC G11C 5/063; G11C 11/221; G11C 11/2257; G11C 11/2273; G11C 11/2275; G11C 11/2297; H10B 53/40

(57) ABSTRACT

A semiconductor device includes: a cell region including a plurality of memory cells connected to a plurality of word lines, a plurality of plate lines and a plurality of bit lines; and a peripheral circuit region configured to control the cell region, and the peripheral circuit region inputs a first program voltage and a second program voltage having different polarities once, to at least one target cell among the plurality of memory cells, and senses deterioration of the target cell by comparing a voltage of the target bit line connected to the target cell with a predetermined reference voltage, and the peripheral circuit region inputs a recovery voltage higher than the first program voltage and the second program voltage to the target cell when the voltage of the target bit line is lower than the reference voltage.

### CROSS-REFERENCE TO RELATED APPLICATION

This application claims the benefit of priority to Korean Patent Application No. 10-2024-0123416, filed on Sep. 10, 2024, in the Korean Intellectual Property Office, the disclosure of which is incorporated herein by reference in its entirety.

### BACKGROUND

A semiconductor device may provide the ability to write data to and erase data from memory cells, or to read recorded data from memory cells, and the memory cells may have data recorded thereto in various manners. Recently, a Ferroelectric Random Access Memory (FeRAM) has been proposed as a semiconductor device that can record data including a ferroelectric layer, and the FeRAM has the advantage of operating at high speed while having non-volatile characteristics that maintain data even when a power supply is cut off. The FeRAM may record data by changing a polarization state of the ferroelectric layer, and therefore, controlling a relationship between a voltage applied to the ferroelectric layer and the polarization state may greatly affect the performance of FeRAM.

### SUMMARY

Some aspects of the present disclosure provide semiconductor devices with improved reliability and performance by sensing a change in a polarization state of a ferroelectric layer according to a voltage applied to the ferroelectric layer and executing a recovery operation for the ferroelectric layer based on a sensing result.

A semiconductor device according to some implementations of the present disclosure includes: a cell region in which memory cells, connected to word lines, bit lines and plate lines are disposed, each of the memory cells including a switch element and a capacitor connected to the switch element and including a ferroelectric layer; and a peripheral circuit region configured to control the memory cells through the word lines, the bit lines and the plate lines, and the peripheral circuit region turns on the switch element included in a target cell, among the memory cells, to activate the target cell, and while the target cell is activated, the peripheral circuit region inputs a first voltage to a target plate line connected to the target cell and inputs a second voltage, higher than the first voltage, to a target bit line connected to the target cell, and then inputs the second voltage to the target plate line and inputs the first voltage to the target bit line, and when a voltage of the target bit line is lower than a predetermined reference voltage, the peripheral circuit region increases the voltage of the target bit line by a third voltage, higher than the second voltage, to execute a recovery operation for the target cell.

A semiconductor device according to some implementations of the present disclosure includes: a cell region including a plurality of memory cells connected to a plurality of word lines, a plurality of plate lines and a plurality of bit lines; and a peripheral circuit region configured to control the cell region, and the peripheral circuit region inputs a first program voltage and a second program voltage having different polarities once, to at least one target cell among the plurality of memory cells, and senses deterioration of the target cell by comparing a voltage of the target bit line connected to the target cell with a predetermined reference voltage, and the peripheral circuit region inputs a recovery voltage higher than the first program voltage and the second program voltage to the target cell when the voltage of the target bit line is lower than the reference voltage.

A semiconductor device according to some implementations of the present disclosure includes: a cell region including a plurality of memory cells connected to a plurality of word lines, a plurality of plate lines and a plurality of bit lines; and a peripheral circuit region configured to change polarization degrees of each of the plurality of memory cells to record first data or second data in each of the plurality of memory cells, and the peripheral circuit region inputs a predetermined reset voltage to at least one target cell among the plurality of memory cells to reset data of the target cell to the second data, executes a read operation for the target cell to sense deterioration of the target cell, and inputs a recovery voltage higher than the reset voltage to the target cell in which deterioration is sensed.

According to some implementations of the present disclosure, each of the memory cells may include a switch element and a capacitor, and the capacitor may include a ferroelectric layer. When booting the semiconductor device or at a specific time, a voltage applied to the ferroelectric layer and a polarization state according to the applied voltage, with respect to at least one target cell among the memory cells, may be sensed, and a recovery operation for the target cell may be executed, based on the sensing result. Accordingly, the reliability and performance of the semiconductor device for recording data by changing the polarization state of the ferroelectric layer may be improved.

Advantages and effects of the present application are not limited to the foregoing content and may be understood based on the following disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of a semiconductor device;

FIGS. 2 to 4 are schematic diagrams illustrating an example of a memory cell array included in a semiconductor device;

FIG. 5 is a polarization plot illustrating characteristics of an example of a memory cell included in a semiconductor device;

FIGS. 6A, 6B, 7A and 7B are circuit diagrams and polarization plots illustrating an example of a program operation of a semiconductor device;

FIG. 8 is a voltage plot illustrating an example of a read operation of a semiconductor device;

FIG. 9 is a flowchart illustrating an example of a recovery operation of a semiconductor device;

FIG. 10 is a voltage plot illustrating an example of a recovery operation of a semiconductor device;

FIGS. 11 to 13 are diagrams illustrating an example of a recovery operation of a semiconductor device;

FIGS. 14A and 14B are polarization plots illustrating an example of a recovery operation of a semiconductor device;

FIGS. 15A and 15B are a circuit diagram and a voltage plot, respectively, illustrating an example of operation of a semiconductor device;

FIG. 16 is a flowchart illustrating an example of a recovery operation of a semiconductor device;

FIG. 17 is a voltage plot illustrating an example of a recovery operation of a semiconductor device; and

FIGS. 18 to 20 are diagrams illustrating an example of a recovery operation of a semiconductor device.

### DETAILED DESCRIPTION

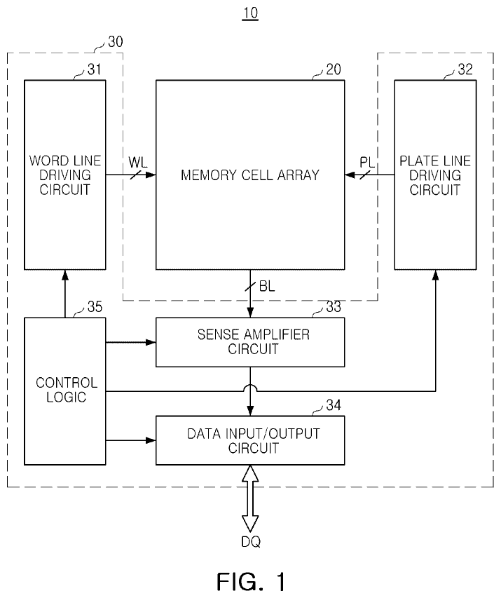

FIG. 1 is a block diagram schematically illustrating a semiconductor device according to some implementations of the present disclosure.

Referring to FIG. 1, a semiconductor device 10 may be a storage device based on a semiconductor element. The semiconductor device 10 may be a random access memory (RAM) device, and may be applied as a main memory to electronic devices such as desktop computers, laptop computers, tablet PCs, and smartphones. The semiconductor device 10 may store data received as a data signal DQ, or read the stored data and output the data as a data signal DQ, in response to an address signal and a control command signal received from an external host (e.g., a central processing unit (CPU), an application processor (AP), a system on a chip (SoC), or the like).

The semiconductor device 10 may include a cell region 20 and a peripheral circuit region 30. The cell region 20 may include a plurality of memory cells, and the plurality of memory cells may be included in a memory cell array. The peripheral circuit region 30 may include a word line driving circuit 31, a plate line driving circuit 32, a sense amplifier circuit 33, a data input/output circuit 34, and a control logic 35, and may control the cell region 20.

A plurality of memory cells included in the cell region 20 may be connected to word lines WL, bit lines BL, and plate lines PL and may be included in a memory cell array. The plurality of memory cells may be connected to the word line driving circuit 31 through the word lines WL, and may be connected to the plate line driving circuit 32 through the plate lines PL. Meanwhile, the plurality of memory cells may be connected to the sense amplifier circuit 33 through the bit lines BL, and the sense amplifier circuit 33 may execute a program operation and a read operation through the bit lines BL. Each of the plurality of memory cells may be disposed at a point at which the word lines WL and the bit lines BL intersect each other.

Each of (e.g., at least some of) the plurality of memory cells may include a switch element and a capacitor connected to the switch element, and the capacitor may include electrodes and a ferroelectric layer. A first electrode of the electrodes included in the capacitor may be connected to the switch element, and a second electrode may be connected to the plate line PL. Meanwhile, the switch element may be implemented with a transistor, and a gate of the transistor may be connected to the word line WL, one of the source/drain regions of the transistor may be connected to the first electrode of the capacitor, and another of the source/drain regions of the transistor may be connected to the bit line BL. The peripheral circuit region 30 may record data by changing a polarization state and a polarization degree of the ferroelectric layer in the capacitor included in the memory cell.

The control logic 35 may receive an address signal and a control command signal from an external host. The address signal may include a row address indicating a row in the memory cell array of the cell region 20 and a column address indicating a column in the memory cell array. For example, the word line driving circuit 31 may determine a selected word line among a plurality of word lines WL by referring to the row address, and the plate line driving circuit 32 and the sense amplifier circuit 33 may determine a selection plate line and a selected bit line by referring to the column address.

The sense amplifier circuit 33 may include a plurality of sense amplifiers connected to the cell region 20 through a plurality of bit lines BL. For example, when the read operation is executed, the sense amplifier connected to the selected bit line may read data from a selected memory cell connected to the selected bit line. The data input/output circuit 34 may output the data read by the sense amplifier as the data signal DQ.

When the program operation is executed, a predetermined program voltage may be applied to the selected bit line and the selection plate line connected to the selected memory cell in a state in which the switch element included in the selected memory cell is turned on. In some implementations, the program voltage is determined by a difference between a voltage applied to the selection plate line and a voltage applied to the selected bit line, and the polarization degree of the ferroelectric layer included in the capacitor of the selected memory cell may be changed by the program voltage. The polarization degree may include a polarization direction and/or a polarization degree (e.g., magnitude of polarization) of the ferroelectric layer.

In this manner, the polarization degree of the ferroelectric layer included in the capacitor of the memory cell may be changed by a voltage applied to the memory cell. The polarization degree of the ferroelectric layer and the voltage applied to the memory cell may have a relationship defined by a hysteresis curve. When a specific voltage is continuously applied to the memory cell, the relationship between the voltage and the polarization degree expressed by the hysteresis curve may be changed, which may lead to a deterioration in the characteristics of the memory cell and the performance of the semiconductor device 10.

In some implementations according to the present disclosure, a change in the characteristics of a memory cell may be sensed, and a recovery operation may be executed for the corresponding memory cell according to a sensing result thereof. Accordingly, the performance degradation of the semiconductor device 10 may be minimized to improve reliability, and a lifespan of the semiconductor device 10 may also be improved.

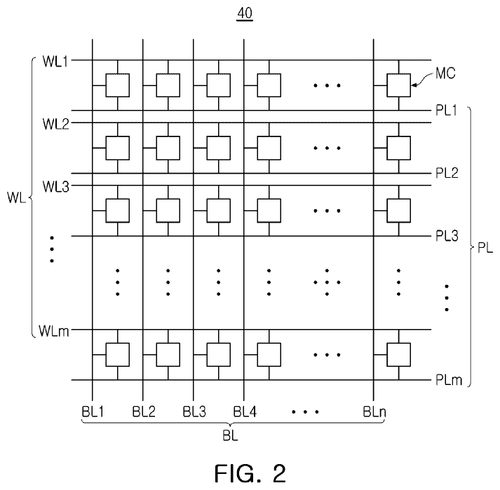

FIGS. 2 to 4 are schematic diagrams illustrating a memory cell array included in a semiconductor device.

First, referring to FIG. 2, a memory cell array 40 may include a plurality of memory cells MC connected to a plurality of word lines WL1 to WLm (WL), a plurality of plate lines PL1 to PLm (PL), and a plurality of bit lines BL1 to BLn (BL). The number of the plurality of word lines WL, the plurality of plate lines PL, the plurality of bit lines BL and the plurality of memory cells MC may vary in different implementations. The plurality of memory cells MC may be disposed at points at which the plurality of word lines WL, the plurality of plate lines PL and the plurality of bit lines BL intersect each other.

As described above with reference to FIG. 1, the plurality of word lines WL may be connected to a word line driving circuit, the plurality of plate lines PL may be connected to a plate line driving circuit, and the plurality of bit lines BL may be connected to a sense amplifier circuit. When a selected word line selected by the word line driving circuit and a selection plate line selected by the plate line driving circuit are determined, a program operation, a read operation and a recovery operation may be executed for selected memory cells connected to the selected word line and the selection plate line. Each of the plurality of bit lines BL may be connected to different sense amplifiers included in the sense amplifier circuit, so that each of the selected memory cells may be individually controlled.

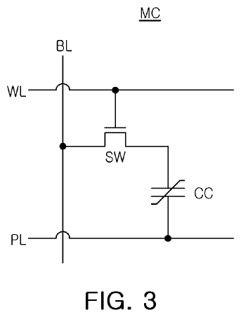

FIG. 3 is a circuit diagram illustrating a memory cell MC. Referring to FIG. 3, a memory cell MC included in a semiconductor device acco may include a switch element SW and a capacitor CC connected to each other. The switch element SW may be implemented with, for example, a transistor, and a gate of the transistor may be connected to a word line WL. Meanwhile, one of the source/drain regions of the switch element SW may be connected to a bit line BL, and the other thereof may be connected to a capacitor CC. The capacitor CC may include a ferroelectric layer and may be connected to a plate line PL.

When the semiconductor device selects the memory cell MC by an address signal received from the external host, the switch element SW may be turned on by a voltage applied to the word line WL. Then, a program operation of changing a polarization degree of the capacitor CC by the voltage applied to each of the bit line BL and the plate line PL, a read operation of reading data recorded in the memory cell MC by determining the polarization degree of the capacitor CC, and the like, may be executed. The program operation and the read operation will be described below.

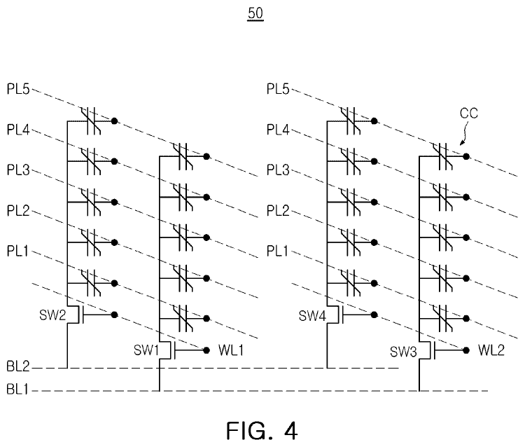

Referring to FIG. 4, a memory cell array 50 may include a plurality of memory cells connected to a plurality of word lines WL1 to WL2, a plurality of plate lines PL1 to PL5, and a plurality of bit lines BL1 to BL2. In some implementations, as illustrated in FIG. 4, some of the plurality of memory cells may share a single switch element SW. Referring to FIG. 4, a plurality of capacitors CC may be connected to a first switch element SW1 connected to a first bit line BL1 and a first word line WL1.

As illustrated in FIG. 4, the plurality of capacitors CC may be connected to different plate lines PL1 to PL5. For example, the plurality of capacitors CC connected to the first switch element SW may be matched one-to-one with the plurality of plate lines PL1 to PL5. Accordingly, the polarization degree of each of the plurality of capacitors CC sharing a single switch element may be individually controlled.

For example, in a state in which the first switch element SW1 and a second switch element SW2 are turned on by a voltage applied to the first word line WL1, only a polarization degree of the capacitor CC connected to the first plate line PL may be changed by the voltage applied to the first bit line BL1 and the first plate line PL1. In order to selectively change only the polarization degree of the capacitor CC connected to the first plate line PL, the same voltage as the first bit line BL1 may be applied to the second to fifth plate lines PL2 to PL5, or the second to fifth plate lines PL2 to PL5 may be floated.

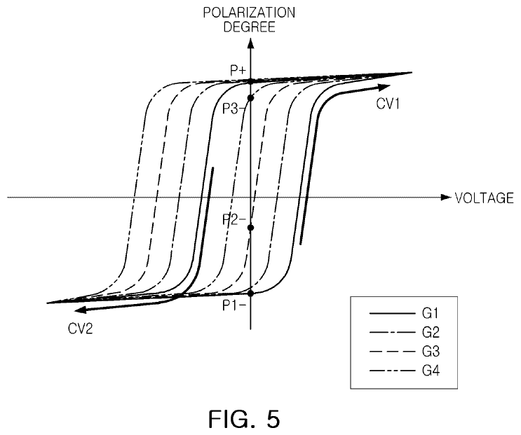

As described with reference to FIGS. 2 to 4, the memory cell of the semiconductor device includes the capacitor CC, and the capacitor CC may include a ferroelectric layer. The polarization degree of the ferroelectric layer may vary depending on the voltage applied to the memory cell, and for example, the relationship between the voltage and the polarization degree may be expressed as a hysteresis curve. Hereinafter, this will be described in more detail with reference to FIG. 5.

FIG. 5 is a view illustrating characteristics of a memory cell included in a semiconductor device. FIG. 5 is a graph illustrating the relationship between the voltage applied to the memory cell and the polarization degree of the ferroelectric layer included in the memory cell. As illustrated in FIG. 5, the relationship between the voltage applied to the memory cell and the polarization degree of the ferroelectric layer included in the memory cell may be expressed as a hysteresis curve.

Referring to a first graph G1, under the condition that a positive voltage is applied to the memory cell, the polarization degree of the ferroelectric layer may increase in a specific direction along a first curve CV1. For example, a voltage of the plate line connected to the memory cell may be set to be higher than a voltage of the bit line connected to the memory cell, so that the positive voltage may be applied to the memory cell. The polarization degree of the ferroelectric layer may be changed by the positive voltage applied to the memory cell. Then, even if the voltage applied to the memory cell is cut off, the polarization degree of the ferroelectric layer may be maintained as a first positive polarization degree (P+).

On the other hand, when a negative voltage is applied to the memory cell, the polarization degree of the ferroelectric layer may be changed in a different direction from the first positive polarization degree (P+) along a second curve CV2. The voltage of the plate line connected to the memory cell may be set to be lower than the voltage of the bit line connected to the memory cell, the negative voltage may be applied to the memory cell. The polarization degree of the ferroelectric layer included in the memory cell may be reduced to a first negative polarization degree (P1−) by the negative voltage, and even if the voltage applied to the memory cell is cut off, the first negative polarization degree (P1−) may be maintained.

In this manner, data may be recorded in the memory cell by changing the polarization degree of the ferroelectric layer to one of a negative direction and a positive direction. For example, a state in which the polarization degree of the ferroelectric layer is changed to the negative direction may be defined as a state in which first data is recorded in the memory cell, and a state in which the polarization degree of the ferroelectric layer is changed to the positive direction may be defined as a state in which second data is recorded in the memory cell. Assuming that 1 bit of data is recorded in the memory cell, one of the first data and the second data may correspond to ‘0,’ and the other thereof may correspond to ‘1.’

However, when one of the positive voltage or the negative voltage is repeatedly applied to the memory cell due to an operation of the semiconductor device, the hysteresis curve indicating the relationship between the voltage and the polarization degree may not be maintained as the first graph G1 and may be moved in a horizontal direction. For example, when the positive voltage is repeatedly applied to the memory cell, the relationship between the voltage and the polarization degree expressed by the first graph G1 as illustrated in FIG. 5 may be moved to the left as in a second graph G2 and a third graph G3.

The movement of the hysteresis curve in the horizontal direction may denote that characteristics of the memory cell are changed. For example, referring to the third graph G3, the polarization degree of the ferroelectric layer according to the program operation of applying the positive voltage to the memory cell is not significantly different from the first positive polarization degree (P+) whereas the polarization degree of the ferroelectric layer according to the program operation of applying the negative voltage to the memory cell may be changed from the first negative polarization degree (P1−) to a second negative polarization degree (P2−). In some cases, as illustrated in FIG. 5, an absolute value of the second negative polarization degree (P2−) may be less than an absolute value of the first negative polarization degree (P1−).

In some implementations, the read operation for the memory cell is executed by applying a read voltage, which is a positive voltage, to the memory cell in a state in which the switch element included in the memory cell is turned on. For example, in the case of a memory cell in which the first data is recorded, since the ferroelectric layer has the positive polarization degree (P+), the polarization degree of the ferroelectric layer may not be changed much by the read voltage, which is the positive voltage. Accordingly, the voltage of the capacitor including the ferroelectric layer may be sensed to be relatively small. On the other hand, in the case of a memory cell in which the second data is recorded, since the ferroelectric layer has a negative polarization degree (P1− or P2−), the polarization degree of the ferroelectric layer may be changed relatively greatly by the read voltage, which is a positive voltage, and the voltage of the capacitor may be sensed to be relatively large in the read operation.

In the read operation, the voltage of the capacitor may be sensed from the bit line connected to the memory cell, or the like, and may be determined based on a difference between the polarization degree of the ferroelectric layer of the memory cell before the read operation and a polarization degree of the ferroelectric layer due to the read voltage applied to the memory cell. Accordingly, when the hysteresis curve indicating the characteristics of the memory cell moves from the first graph G1 to the third graph G3, the voltage of the capacitor sensed in the read operation for the memory cell in which the second data is recorded may decrease, which may lead to a decrease in the performance and reliability of the semiconductor device. When the movement of the hysteresis curve becomes severe, it may be impossible to program the second data for the corresponding memory cell.

In some implementations, a recovery operation for the memory cell is executed by allocating some time during the booting of the semiconductor device or during the operation of the semiconductor device. The recovery operation may be an operation of restoring the relationship between the voltage and polarization degree in the memory cell to a state close to the first graph G1 when the relationship therebetween is changed as in the third graph G3. Accordingly, the characteristics of the memory cell may be restored by the recovery operation, thereby improving the performance and reliability of the semiconductor device and extending and a lifespan thereof.

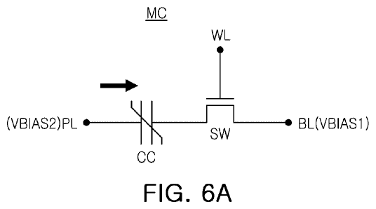

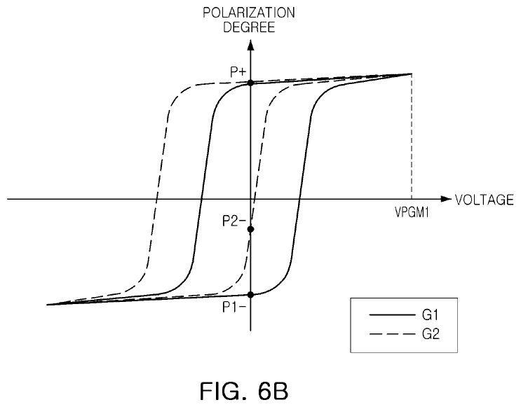

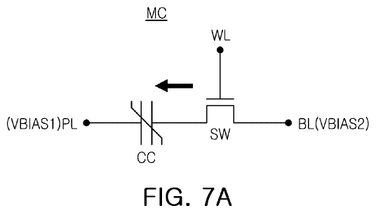

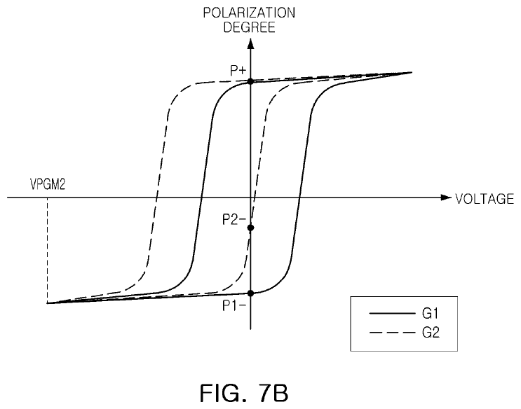

FIGS. 6A, 6B, 7A and 7B illustrate a program operation of a semiconductor device. FIGS. 6A and 6B illustrate a program operation for recording first data to a memory cell MC. Referring to FIG. 6A, in a program operation of recording the first data, a switch element SW may be turned on by a voltage applied to a word line WL, and in a state in which the switch element SW is turned on, a first bias voltage VBIAS1 may be applied to a bit line BL, and a second bias voltage VBIAS2 may be applied to a plate line PL. The second bias voltage VBIAS2 may be higher than the first bias voltage VBIAS1, and the first bias voltage VBIAS1 may be a reference voltage such as a ground voltage.

A difference between the first bias voltage VBIAS1 and the second bias voltage VBIAS2 may be defined as a first program voltage VPGM1, and the first program voltage VPGM1 may be a positive voltage. Referring to FIG. 6B illustrating a hysteresis curve of the memory cell MC, the polarization degree of the ferroelectric layer included in the capacitor CC may be changed to a positive polarization degree (P+) by the first program voltage VPGM1. Even after the voltage supply to each of the plate line PL and the bit line BL is cut off, the polarization degree of the ferroelectric layer may be maintained as the positive polarization degree (P+), and the first data recorded in the memory cell MC may be maintained. Depending on a degree of deterioration of the memory cell MC, in the first program operation, the polarization degree of the ferroelectric layer may be changed from the first negative polarization degree (P1−) to the positive polarization degree (P+), or from the second negative polarization degree (P2−) to the positive polarization degree (P+).

FIGS. 7A and 7B illustrate a program operation of recording second data into a memory cell MC. Referring to FIG. 7A, in the program operation for recording the second data, a switch element SW may be turned on by a voltage applied to a word line WL, and a first bias voltage VBIAS1 may be applied to a plate line PL and a second bias voltage VBIAS2 may be applied to a bit line BL. Similarly to the example explained with reference to FIG. 6A, the second bias voltage VBIAS2 may be higher than the first bias voltage VBIAS1, and the first bias voltage VBIAS1 may be a reference voltage such as a ground voltage.

A difference between the first bias voltage VBIAS1 and the second bias voltage VBIAS2 may be defined as a second program voltage VPGM2, and the second program voltage VPGM2 may be a negative voltage. For example, magnitudes of the first program voltage VPGM1 and the second program voltage VPGM2 may be the same, but polarities thereof may be opposite to each other.

Referring to FIG. 7B illustrating a hysteresis curve of a memory cell MC, a polarization degree of a ferroelectric layer included in a capacitor CC may be changed from a positive polarization degree (P+) to a negative polarization degree (P1− or P2−) by the second program voltage VPGM2. Even after a voltage supply to each of the plate line PL and the bit line BL is cut off, the polarization degree of the ferroelectric layer may be maintained as the negative polarization degree (P1− or P2−), and the second data recorded in the memory cell MC may be maintained.

Depending on the degree of deterioration of the memory cell MC, in the second program operation, the polarization degree of the ferroelectric layer may be changed from the positive polarization degree (P+) to the first negative polarization degree (P1−) or the second negative polarization degree (P2−). When a specific voltage is repeatedly applied to the memory cell MC, for example, when the positive voltage is repeatedly applied to the memory cell MC, the hysteresis curve may be changed more to the left. In this case, the polarization degree of the ferroelectric layer, which has been reduced to the first negative polarization degree (P1−) by the second program voltage VPGM2, may be increased to a value greater than the second negative polarization degree (P2−) after an input of the second program voltage VPGM2 is terminated.

The memory cell MC may be deteriorated due to causes such as a repeated application of a specific voltage to the memory cell MC, and the deterioration of the memory cell MC may be represented as a horizontal movement of the hysteresis curve. As illustrated in FIG. 7B, when the hysteresis curve is moved to the left, the polarization degree of the ferroelectric layer reduced to the first negative polarization degree (P1−) during the application of the second program voltage VPGM2 may be increased after the input of the second program voltage VPGM2 is terminated. In the case of severe deterioration of the memory cell MC, the polarization degree of the ferroelectric layer may be changed to a positive polarization degree after the input of the second program voltage VPGM2 is terminated, in which case it may be impossible to program the second data.

Conversely, when the hysteresis curve is moved to the right, the polarization degree of the ferroelectric layer reduced to the first positive polarization degree (P1+) during the application of the first program voltage VPGM1 may be reduced after the input of the first program voltage VPGM1 is terminated. In the case of severe deterioration of the memory cell MC, the polarization degree of the ferroelectric layer may be changed to a negative polarization after the input of the first program voltage VPGM1 is terminated, in which case it may be impossible to program the first data.

In some implementations, a recovery operation for compensating for the deterioration of the memory cell MC as described above may be executed in the semiconductor device. The recovery operation may be executed after an operation of sensing the deterioration of the memory cell MC, and, in some implementations, may be executed only for the memory cell MC in which the deterioration is sensed. For example, the deterioration of the memory cell MC may be determined by sequentially inputting voltages of different signs to the memory cell MC and measuring the voltage of the capacitor included in the memory cell MC at the bit line BL or the plate line PL. For the memory cell MC in which the deterioration is sensed, the recovery operation of inputting a voltage higher than the first program voltage VPGM1 and the second program voltage VPGM2 may be executed.

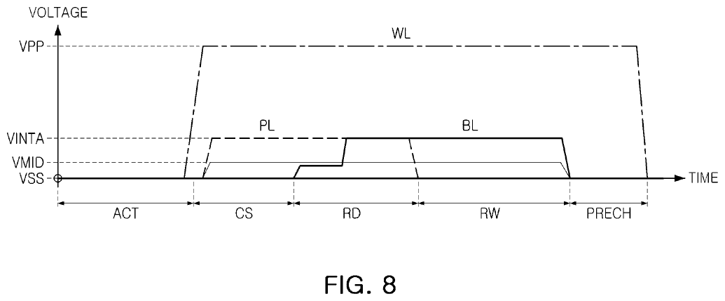

FIG. 8 is a view illustrating a read operation of a semiconductor device. Referring to FIG. 8, a read operation may include an activation section ACT, a charge sharing section CS, a sensing section RD, a write section RW, and a precharge section PRECH. First, in the activation section ACT, a turn-on voltage VPP may be input to a selection word line WL connected to a selection cell (e.g., a cell that has been selected). Accordingly, a switch element included in the selection cell may be turned on, and the selection cell may be activated.

Then, in the charge sharing section CS, a first voltage VSS may be input to a selection bit line BL connected to the selection cell, and a second voltage VINTA may be input to a selection plate line PL connected to the selection cell. In some implementations, the first voltage VSS is a ground voltage, and/or the second voltage VINTA is higher than the first voltage VSS and lower than the turn-on voltage VPP. A positive voltage may be applied to the selection cell by the first voltage VSS and the second voltage VINTA, and a polarization degree of a capacitor included in the selection cell may be set to a positive polarization degree.

In the sensing section RD, the voltage of the capacitor included in the selection cell to which the first voltage VSS and the second voltage VINTA are applied may be sensed by the sense amplifier from the selection bit line BL. For example, assuming that first data D0 has been recorded to the selection cell before the beginning of the read operation, since the polarization degree of the capacitor included in the selection cell hardly changes in the charge sharing section CS, the voltage of the selection bit line BL may hardly change from the first voltage VSS.

On the other hand, assuming that second data D1 has been recorded in the selection cell before the beginning of the read operation, since the polarization degree of the capacitor included in the selection cell is changed from a negative polarization degree to a positive polarization degree in the charge sharing section CS, the voltage of the selection bit line BL may increase relatively significantly. The sense amplifier may amplify the voltage of the selection bit line BL in the sensing section RD and may compare the amplified voltage with a reference voltage.

In some implementations, as illustrated in FIG. 8, the reference voltage compared with the voltage of the selection bit line BL may be an intermediate voltage VMID. As illustrated in FIG. 8, when the voltage of the selection bit line BL is lower than the reference voltage, data of the selection cell may be read as the first data DO, and when the voltage of the selection bit line BL is higher than the reference voltage, the data of the selection cell may be read as the second data D1.

When (e.g., after) the data of the selection cell is read, the voltage of the selection plate line PL may be reduced to the first voltage VSS. Then, a write operation of restoring the data of the selection cell changed in the charge sharing section CS may be executed during the write section RW. By the positive voltage input to the selection cell in the charge sharing section CS, the data of the selection cell may be changed to the first data DO.

Accordingly, as illustrated in FIG. 8, when the data of the selection cell is read as the first data DO, a separate write operation may not be executed. On the other hand, when the data of the selection cell is read as the second data D1, the voltage of the selection bit line BL may be maintained at the second voltage VINTA during the write section RW, the second data D1 may be recorded again in the selection cell in which the first data D0 has been recorded in the charge sharing section CS. When the write section RW is terminated, an operation of reducing the voltage of the selection bit line BL to the first voltage VSS may be performed during the precharge section PRECH.

As described with reference to FIG. 8, a positive voltage may be applied to the selection cell during the charge sharing section CS of the read operation. When the data recorded in the selection cell is the second data D1, since an operation of recording the second data D1 again by applying a negative voltage to the selection cell during the write section RW is executed, deterioration of the selection cell that may occur due to only a positive voltage being repeatedly applied to the selection cell may be prevented to some extent.

On the other hand, when the data recorded in the selection cell is the first data DO, the positive voltage may be applied to the selection cell to record the first data DO, and the positive voltage may also be applied to the selection cell during the charge sharing section CS of the read operation. Since only the positive voltage is repeatedly applied to the selection cell, as described above with reference to FIGS. 6B and 7B, the hysteresis curve indicating the relationship between the voltage and the polarization degree of the ferroelectric layer included in the selection cell may be moved to the left. Accordingly, it may be difficult or impossible to record the second data in the selection cell, or a difference between the positive polarization degree and the negative polarization degree may decrease, thereby degrading the accuracy of the read operation.

In some implementations according to the present disclosure, a recovery operation for solving the above-described problem may be executed in the semiconductor device. In the semiconductor device, prior to the recovery operation for the memory cell, a sensing operation for determining deterioration of the memory cell may first be executed, and in the sensing operation, the negative voltage and the positive voltage may be sequentially applied to the memory cell.

In a case in which the difference between the positive polarization degree and the negative polarization degree in the ferroelectric layer included in the capacitor decreases due to the deterioration of the memory cell, a voltage change of the capacitor may be small in the memory cell to which the negative voltage and the positive voltage are sequentially applied. On the other hand, in a case in which the deterioration of the memory cell is not severe, the difference between the positive polarization degree and the negative polarization degree in the ferroelectric layer included in the capacitor may be sufficiently secured, so that the voltage change of the capacitor may be relatively large in the memory cell to which the negative voltage and the positive voltage are sequentially applied. Accordingly, the deterioration of the memory cell may be sensed and whether or not the recovery operation is performed may be determined by sequentially applying the negative voltage and the positive voltage to the memory cell, and measuring the voltage of the capacitor included in the memory cell.

For example, the operation of sensing the deterioration of the memory cell and the recovery operation, and the like, may be executed by the peripheral circuit region of the semiconductor device. When the voltage of the capacitor sensed by the sense amplifier from the memory cell to which the negative voltage and the positive voltage are sequentially applied is lower than a predetermined reference voltage, the peripheral circuit region may determine that the memory cell has deteriorated and may perform the recovery operation. The reference voltage compared to the voltage of the capacitor sensed by the sense amplifier may be different from the reference voltage applied to the sensing section RD described with reference to FIG. 8.

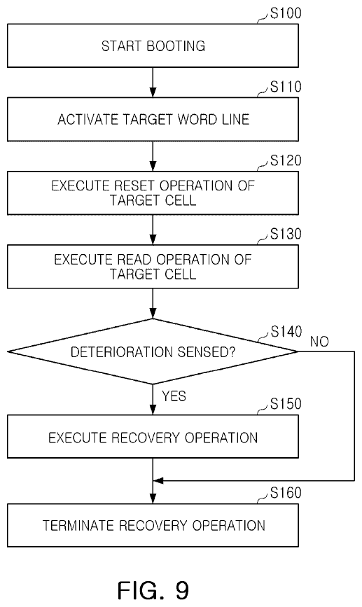

FIG. 9 is a flowchart illustrating a recovery operation of a semiconductor device according to some implementations of the present disclosure.

In some implementations, as described with reference to FIG. 9, the recovery operation for compensating for the deterioration of the memory cell may be performed during booting. When the booting of a system including a semiconductor device begins (S100), the peripheral circuit region of the semiconductor device may activate a target word line (S110). The target word line may be one of a plurality of word lines, and may be a word line connected to a target cell on which the recovery operation is to be executed among the memory cells. The word line driving circuit of the peripheral circuit region may input a turn-on voltage to the target word line, so that a switch element of the target cell connected to the target word line may be turned on.

Next, a reset operation for the target cell may be executed (S120), and in the reset operation, a first program voltage or a second program voltage may be input to the target cell. The first data may be recorded by inputting the first program voltage to the target cell, and the second data may be recorded by inputting the second program voltage, and data recorded in the target cell may be reset to the first data or the second data by the reset operation. When the target cell is reset, the peripheral circuit region may execute a read operation for the target cell (S130).

In the read operation, a charge sharing operation and a sensing operation for the target cell may be executed. In the charge sharing operation, a voltage having an opposite polarity to a voltage input to the target cell in the reset operation of operation S120 may be input. For example, when the second program voltage is input to the target cell in the reset operation, the first program voltage may be input in the charge sharing operation. A polarization degree of the capacitor included in the target cell may be set to a first polarization degree by the first program voltage, and may be set to a second polarization degree different from the first polarization degree by the second program voltage. In the sensing operation, the voltage of the capacitor corresponding to a difference between the first polarization degree and the second polarization degree may be sensed by the sense amplifier through the target bit line connected to the target cell.

The peripheral circuit region may determine whether the deterioration of the target cell occurs by referring to the voltage of the target bit line sensed by the sense amplifier in operation S130 (S140). When the deterioration occurs in the target cell, a difference between the first polarization degree and the second polarization degree may appear relatively small, and a voltage sensed by the sense amplifier in the target bit line may also be reduced. Accordingly, the peripheral circuit region may determine that the deterioration occurs in the target cell when the voltage of the target bit line is lower than a predetermined reference voltage. On the other hand, the peripheral circuit region may determine that the deterioration does not occur in the target cell when the voltage of the target bit line is higher than the reference voltage.

When the deterioration is sensed in operation S140, the peripheral circuit region may execute a recovery operation (S150). The recovery operation may be an operation of applying a recovery voltage to the target cell in which the deterioration is sensed. A charge imbalance of the capacitor included in the target cell may be resolved by the recovery voltage.

The recovery voltage may vary depending on the cause and type of the deterioration occurring in the target cell. For example, the deterioration of the target cell may occur due to a decrease in the difference between the first polarization degree and the second polarization degree, which may occur due to a decrease in the first polarization degree or an increase in the second polarization degree. When the deterioration of the target cell is caused by the increase in the second polarization degree, the recovery voltage may be input to the target cell by applying a higher voltage to a target bit line than to a target plate line. When the deterioration of the target cell is caused by the decrease in the first polarization degree, the recovery voltage may be input to the target cell by applying a higher voltage to the target plate line than to the target bit line.

When the recovery voltage is input to the target cell, a precharge operation of initializing the voltage of the target bit line connected to the target cell may be executed and the recovery operation may be terminated (S160). Meanwhile, when the deterioration is not sensed in operation S140, the recovery voltage may not be input to the target cell, and the precharge operation of initializing the voltage of the target bit line may be executed and the recovery operation may be terminated.

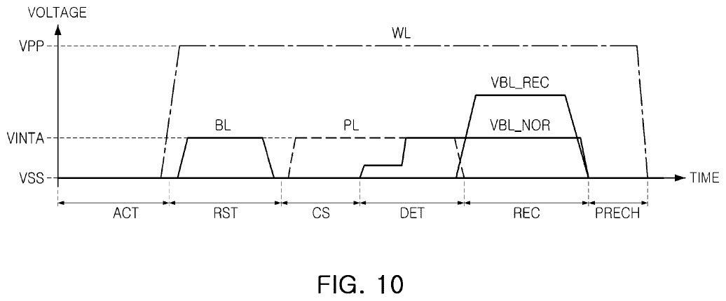

FIG. 10 is a view illustrating a recovery operation of a semiconductor device according to some implementations of the present disclosure.

Referring to FIG. 10, a recovery operation may include an activation section ACT, a reset section RST, a charge sharing section CS, a detection section DET, a recovery section REC, and a precharge section PRECH. In the activation section ACT, a turn-on voltage VPP may be input to a target word line WL connected to a target cell. By the turn-on voltage, a switch element included in the target cell may be turned on, and the target cell may be activated.

In the reset section RST, data of the target cell may be reset. In some implementations, as illustrated in FIG. 10, during the reset section RST, a first voltage VSS may be input to a target plate line PL connected to the target cell, and a second voltage VINTA higher than the first voltage VSS may be input to a target bit line BL. In some implementations, the first voltage VSS may be a power supply voltage, and/or the second voltage VINTA may be higher than the first voltage VSS and lower than the turn-on voltage VPP.

In some implementations (e.g., at least when the target cell is a cell having a structure similar to the memory cell MC described with reference to FIGS. 6A and 7A), data of the target cell may be reset to the second data by the reset operation. Additionally, since a higher voltage is applied to the target bit line BL than the target plate line PL, a negative voltage may be applied to the target cell, and a polarization degree of the ferroelectric layer included in the capacitor of the target cell may be set to a negative polarization degree.

In the charge sharing section CS, the first voltage VSS may be input to the target bit line BL, and the second voltage VINTA may be input to the target plate line PL. A positive voltage may be applied to the target cell by the first voltage VSS and the second voltage VINTA, and the polarization degree of the ferroelectric layer included in the capacitor of the target cell may be changed from the negative polarization degree to the positive polarization degree.

During the detection section DET after the charge sharing section CS, a sense amplifier connected to the target bit line BL may sense a voltage change of the capacitor included in the target cell. The voltage change sensed by the sense amplifier from the capacitor of the target cell in the detection section DET may vary depending on the degree of the deterioration of the target cell. When the deterioration of the target cell is severe, a difference between the negative polarization degree set in the ferroelectric layer included in the capacitor of the target cell during the reset section RST and a positive polarization degree set in the ferroelectric layer included in the capacitor of the target cell during the charge sharing section CS may be small. Accordingly, a magnitude of the voltage sensed by the sense amplifier from the target bit line BL in the detection section DET may be lower. On the other hand, when the deterioration of the target cell is not severe, the magnitude of the voltage sensed by the sense amplifier from the target bit line BL in the detection section DET may be relatively high.

The sense amplifier may compare a voltage detected from the target bit line BL during the detection section DET with a predetermined reference voltage. The reference voltage input to the sense amplifier during the detection section DET may be higher than a reference voltage input to the sense amplifier during a general read operation. For example, the reference voltage input to the sense amplifier during the detection section DET may be set to be higher than the reference voltage input to the sense amplifier during a general read operation, so that the deterioration of the target cell may be sensed more strictly. As such, even minute deterioration that has occurred in the target cell may be detected during the detection section DET.

During the recovery section REC, the peripheral circuit region may execute a recovery operation for the target cell based on a determination result in the detection section DET. For example, when the degradation is determined to be present in the target cell as a result of the determination in the detection section DET, the sense amplifier may increase the voltage of the target bit line BL to a recovery voltage VBL_REC higher than the second voltage VINTA.

During the recovery section REC, the target plate line PL may be reduced to the first voltage VSS, and thus, the voltage of the target bit line BL may be increased to the recovery voltage VBL_REC, thus applying a significantly high negative voltage to the target cell. Accordingly, it may be possible to compensate for the deterioration occurring in the target cell to which a positive voltage is repeatedly applied. The deterioration occurring in the target cell to which the positive voltage is repeatedly applied may include, for example, charge imbalance occurring in a capacitor.

Meanwhile, when it is determined that no deterioration is present in the target cell as a result of the determination in the detection section DET, the sense amplifier may maintain the voltage of the target bit line BL as a general bit line voltage VBL_NOR that is substantially the same as the second voltage VINTA. Then, when the recovery section REC is terminated, a precharge operation of reducing the voltage of the target bit line BL to the first voltage VSS may be executed during the precharge section PRECH. For example, the precharge operation may be performed when, or in response to, elapse of a predetermined time after sensing in the detection section DET, e.g., a predetermined time after the voltage of the target bit line BL is sensed to be lower than the predetermined reference voltage.

In some implementations, as described with reference to FIG. 10, the recovery operation may include an operation of inputting voltages having different polarities to the target cell once in a state in which the target word line WL is activated, and then detecting a voltage change of the capacitor included in the target cell from the target bit line BL. As described with reference to the hysteresis curve of FIG. 5, as the deterioration of the target cell is more severe, the voltage change of the capacitor may appear relatively small.

A first input terminal of the sense amplifier may be connected to the target bit line BL, and the other second input terminal may receive a reference voltage. When the voltage change of the capacitor detected from the target cell through the target bit line BL is lower than the reference voltage, a control logic connected to the sense amplifier may determine that the deterioration is present in the target cell and may perform the recovery operation. In the recovery operation, a negative voltage having a larger absolute value than a voltage applied to the target cell in a normal read operation and a normal program operation may be applied to the target cell. Accordingly, the cause of the deterioration of the target cell, such as charge imbalance of the capacitor, may be resolved, and the reliability and performance of the semiconductor device may be improved and a lifespan thereof may be enhanced by compensating for the deterioration of the target cell.

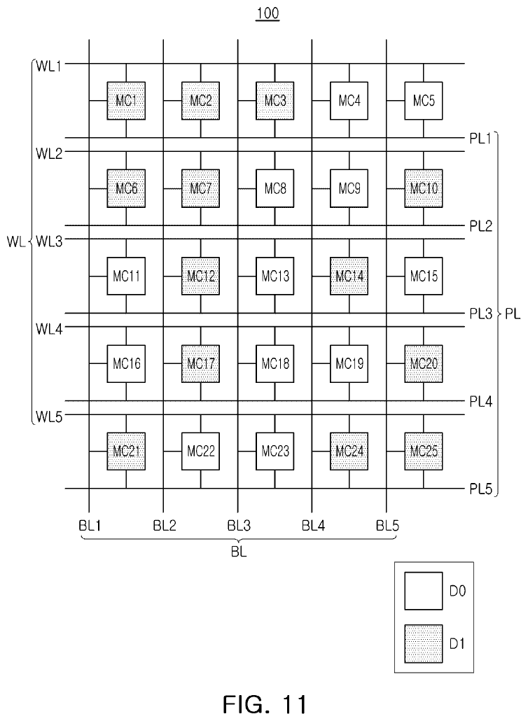

FIGS. 11 to 13 are views illustrating a recovery operation of a semiconductor device according to some implementations of the present disclosure.

A semiconductor device 100 described with reference to FIGS. 11 to 13 may include a plurality of memory cells MC1 to MC25, and the plurality of memory cells MC1 to MC25 may be connected to a plurality of word lines WL1 to WL5 (WL), a plurality of plate lines PL1 to PL5 (PL), and a plurality of bit lines BL1 to BL5 (BL). A voltage of each of the plurality of word lines WL may be controlled by a word line driving circuit included in a peripheral circuit region of the semiconductor device 100, and a voltage of each of the plurality of plate lines PL may be controlled by a plate line driving circuit included in a peripheral circuit region of the semiconductor device 100. The plurality of bit lines BL may be connected to sense amplifiers included in a sense amplifier circuit. The number of the plurality of memory cells MC1 to MC25 may vary depending on the implementation.

Each of the plurality of memory cells MC1 to MC25 may have a first program state in which first data D0 is recorded or a second program state in which second data D1 is recorded. A program state of the plurality of memory cells MC1 to MC25 may be determined by voltages applied to the plurality of plate lines PL and the plurality of bit lines BL. For example, in a state in which the first word line WL1 is selected, a first bias voltage may be applied to the fifth bit line BL5 and a second bias voltage higher than the first bias voltage may be applied to the fifth plate line PL5, so that the first data D0 may be recorded in the fifth memory cell MC5. Meanwhile, in a state in which the first word line WL1 is selected, the second bias voltage may be applied to the first bit line BL1 and the first bias voltage may be applied to the first plate line PL1, so that the second data D1 may be recorded in the first memory cell MC1.

FIG. 11 is a view illustrating a program state of each of the plurality of memory cells MC1 to MC25 at the time when a power source of the system including the semiconductor device 100 is cut off. Each of the plurality of memory cells MC1 to MC25 may include a switch element and a capacitor, and the first data D0 or the second data D1 may be recorded by changing a polarization degree of a ferroelectric layer included in the capacitor. Since the polarization degree of the ferroelectric layer included in the capacitor is unchangeably maintained in the state in which the power is cut off, a program state of each of the plurality of memory cells MC1 to MC25 may be maintained in a state illustrated in FIG. 11 even after the power source of the system is cut off.

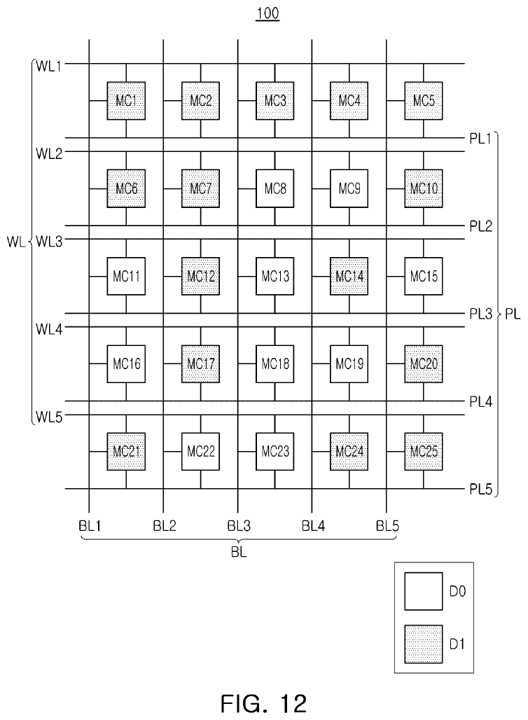

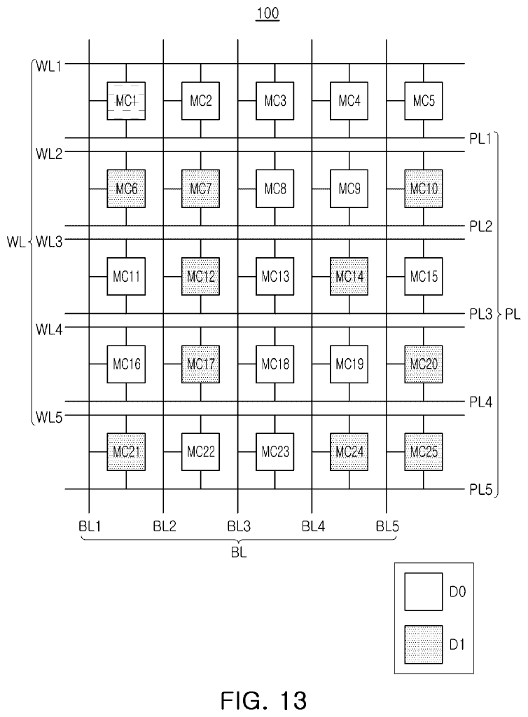

After the power is supplied to the system again and the semiconductor device 100 begins booting, the semiconductor device 100 may perform a recovery operation of compensating for the deterioration of at least portions of the plurality of memory cells MC1 to MC25. In some implementations, the semiconductor device 100 sequentially performs the recovery operation for the plurality of word lines WL. Hereinafter, the recovery operation for the first to fifth memory cells MC1 to MC5 connected to the first word line WL1 will be described with reference to FIGS. 12 and 13 together with FIG. 10.

In order to perform the recovery operation, the first word line WL1 may be activated first. The word line driving circuit may input a turn-on voltage VPP to the first word line WL1, and the switch elements included in each of the first to fifth memory cells MC1 to MC5 may be turned on by the turn-on voltage VPP.

In a state in which the turn-on voltage VPP is input to the first word line WL1, the plate line driving circuit may input a first voltage VSS to the plurality of plate lines PL1 to PL5, and the sense amplifier circuit may input a second voltage VINTA to the plurality of bit lines BL1 to BL5. Accordingly, as illustrated in FIG. 12, the second data D1 may be recorded in the first to fifth memory cells MC1 to MC5, and the first to fifth memory cells MC1 to MC5 may be set to a second program state. The polarization degree of the capacitor included in each of the first to fifth memory cells MC1 to MC5 may be set to a negative polarization degree.

Next, the plate line driving circuit may input the second voltage VINTA to the plurality of plate lines PL1 to PL5, and the sense amplifier circuit may input the first voltage VSS to the plurality of bit lines BL1 to BL5. For example, polarities of voltages applied to each of the first to fifth memory cells MC1 to MC5 may be reversed from each other. Accordingly, the first to fifth memory cells MC1 to MC5 may be set to a first program state, and the polarization degree of the capacitor included in each of the first to fifth memory cells MC1 to MC5 may be changed to a positive polarization degree.

The sense amplifier circuit may sense the voltages of each of the plurality of bit lines BL1 to BL5. The voltages sensed by the sense amplifier circuit from each of the plurality of bit lines BL1 to BL5 may be voltages generated in a process in which the first to fifth memory cells MC1 to MC5 change from a second program state to a first program state. For example, the polarization degree of the capacitor included in each of the first to fifth memory cells MC1 to MC5 may change from the negative polarization degree to the positive polarization degree, thereby changing the voltages of each of the bit lines BL1 to BL5.

A control logic of the peripheral circuit region may determine whether each of the first to fifth memory cells MC1 to MC5 is deteriorated using the voltages sensed by the sense amplifier circuit in each of the bit lines BL1 to BL5. A difference between the negative polarization degree and the positive polarization degree in the capacitor of a severely deteriorated cell may be smaller than a difference between the negative polarization degree and the positive polarization degree in the capacitor of a relatively less deteriorated cell. Accordingly, a relatively low voltage may be sensed in the bit line connected to the severely deteriorated cell, and a relatively high voltage may be sensed in the bit line connected to the relatively less deteriorated cell. The sense amplifier circuit may compare the voltages sensed from each of the plurality of bit lines BL1 to BL5 with the reference voltage and may output a sensing signal, and the control logic may determine whether each of the first to fifth memory cells MC1 to MC5 is deteriorated and whether the recovery operation is to be executed, by referring to the sensing signal. When the determination of whether each of the first to fifth memory cells MC1 to MC5 is deteriorated is completed, the control logic may reduce the voltages of the plurality of plate lines PL to the first voltage VSS.

In the example illustrated in FIG. 13, the control logic may determine that the recovery operation is required only for the first memory cell MC1, among the first to fifth memory cells MC1 to MC5. As illustrated in FIG. 10, the control logic may apply a voltage higher than the second voltage VINTA to the first bit line BL1 while maintaining a voltage of the first plate line PL1 connected to the first memory cell MC1 at the first voltage VSS. A recovery voltage higher than the second voltage VINTA may be applied to the first memory cell MC1, and the charge imbalance of the capacitor included in the first memory cell MC1 may be alleviated and/or removed by the recovery voltage.

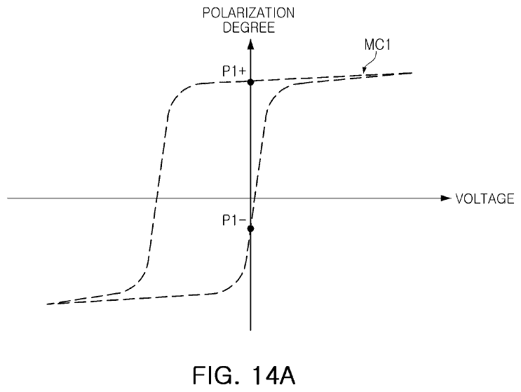

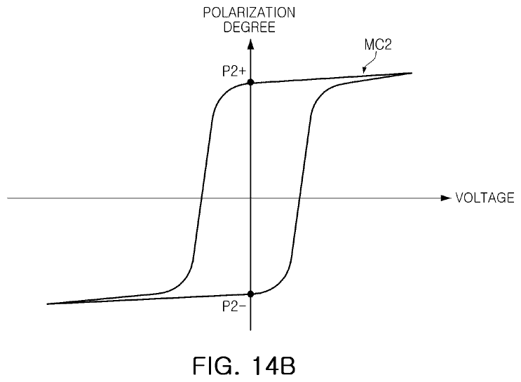

FIGS. 14A and 14B are views illustrating a recovery operation of a semiconductor device according to some implementations of the present disclosure. FIG. 14A is a graph illustrating the characteristics of a first memory cell MC1 selected as a target of the recovery operation in the scenario described above with reference to FIGS. 11 to 13, and FIG. 14B is a graph illustrating the characteristics of a second memory cell MC2 not selected as the target of the recovery operation. FIGS. 14A and 14B are hysteresis curves illustrating a relationship between a voltage applied to a capacitor included in each of the memory cells MC1 and MC2 and a polarization degree of the capacitor according to the voltage applied to the capacitor.

Referring to FIG. 14A, in the first memory cell MC1, the polarization degree of the capacitor may be set to a first positive polarization degree (P1+) by a positive voltage applied to the capacitor, and the polarization degree of the capacitor may be set to a first negative polarization degree (P1−) by a negative voltage applied to the capacitor. Meanwhile, referring to FIG. 14B, in the first memory cell MC1, the polarization degree of the capacitor may be set to a second positive polarization degree (P2+) by the positive voltage applied to the capacitor, and the polarization degree of the capacitor may be set to a second negative polarization degree (P2−) by the negative voltage applied to the capacitor.

Comparing FIGS. 14A and 14B, the graph illustrating the characteristics of the first memory cell MC1, having relatively severe deterioration, represents the graph illustrating the characteristics of the second memory cell MC2, having relatively less deterioration, moved to the left in the horizontal direction. Accordingly, it may be seen that a difference between the first positive polarization degree (P1+) and the second positive polarization degree (P2+) is almost nonexistent whereas a difference between the first negative polarization degree (P1−) and the second negative polarization degree (P2−) may be large. The first negative polarization degree (P1−) may be greater (or closer to zero, or having a smaller magnitude) than the second negative polarization degree (P2−).

In an operation of selecting the target of the recovery operation, voltages having opposite polarities may be sequentially applied to each of the first memory cell MC1 and the second memory cell MC2. In the case of the first memory cell MC1, due to the voltages having opposite polarities sequentially applied, a voltage corresponding to the difference between the first positive polarization degree (P1+) and the first negative polarization degree (P1−) may be output to the first bit line BL1. In the case of the second memory cell MC2, due to the voltages having opposite polarities sequentially applied, a voltage corresponding to the difference between the second positive polarization degree (P2+) and the second negative polarization degree (P2−) may be output to the second bit line BL2. Accordingly, a voltage of the first bit line BL1 may be lower than a voltage of the second bit line BL2.

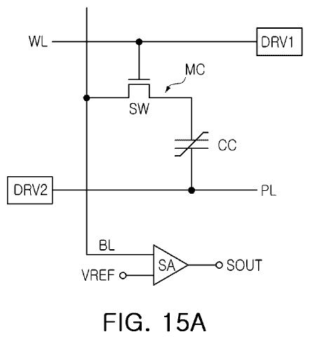

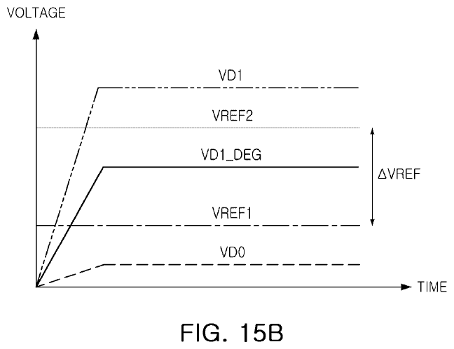

The first bit line BL1 may be connected to the first sense amplifier, and the first sense amplifier may output a first sensing signal by comparing the voltage of the first bit line BL1 with a predetermined reference voltage. The second bit line BL2 may be connected to the second sense amplifier, and the second sense amplifier may output a second sensing signal by comparing the voltage of the second bit line BL2 with the predetermined reference voltage. The control logic of the peripheral circuit region may determine whether to apply the recovery voltage to the first memory cell MC1 based on the first sensing signal, and may determine whether to apply the recovery voltage to the second memory cell MC2 based on the second sensing signal. Hereinafter, an operation of the sense amplifier and an operation of determining whether the memory cell is deteriorated based on the sensing signal output by the sense amplifier will be described with reference to FIGS. 15A and 15B.

FIGS. 15A and 15B are views illustrating an operation of a semiconductor device according to some implementations of the present disclosure. First, referring to FIG. 15A, a memory cell MC may be connected to a word line WL, a plate line PL and a bit line BL, and may include a switch element SW and a capacitor CC, and the capacitor CC may include a ferroelectric layer. A gate of the switch element SW may be connected to the word line WL, and one of source/drain regions of the switch element SW may be connected to the capacitor CC and the other thereof may be connected to the bit line BL. The other of the source/drain regions of the switch element SW may be connected to the plate line PL.

The word line WL may be connected to a first driver DRV1, and the plate line PL may be connected to a second driver DRV2. Voltages of the word line WL and the plate line PL may be individually controlled by the first driver DRV1 and the second driver DRV2. The bit line BL may be connected to a sense amplifier SA, and the sense amplifier SA may sense a voltage of the bit line BL. The voltage of the bit line BL may be controlled by a separate driver or a separate sense amplifier SA connected to the bit line BL.

A program operation for the memory cell MC may be executed by applying a voltage to each of the plate line PL and the bit line BL. For example, by applying a voltage higher than the bit line BL to the plate line PL, first data may be recorded in the memory cell MC, and by applying a voltage lower than the bit line BL to the plate line PL, second data may be recorded in the memory cell MC. In a state in which the first data is recorded, a first polarization degree of the capacitor CC may be different from a second polarization degree of the capacitor CC in a state in which the second data is recorded. As a difference between the first polarization degree and the second polarization degree increases, the reliability of the memory cell MC may be improved and a margin in a read operation may be sufficiently secured.

However, when the program operation of recording specific data, for example, the first data, in the memory cell MC is repeatedly executed, deterioration such as a decrease in the difference between the first polarization degree and the second polarization degree may occur in the memory cell MC. According to some implementations of the present disclosure, an operation of sensing and compensating for the deterioration may be executed for the memory cell MC.

The operation of sensing the deterioration may be performed in a manner of sequentially applying voltages having opposite polarities to the memory cell MC and sensing the voltage of the bit line BL by the sense amplifier SA, in a state in which the switch element SW is turned on by the first driver DRV1. When the deterioration of the memory cell MC is not severe or is nonexistent, that is, when a difference between the first polarization degree and the second polarization degree is sufficiently high, the voltage of the bit line BL may be higher than a reference voltage VREF. On the other hand, when deterioration has occurred in the memory cell MC, that is, when the difference between the first polarization degree and the second polarization degree is not sufficiently high, the voltage of the bit line BL may be lower than the reference voltage VREF. Accordingly, a sensing signal SOUT may be determined differently depending on the degree of deterioration of the memory cell MC, and the control logic of the peripheral circuit region may determine whether the memory cell MC is deteriorated by referring to the sensing signal SOUT.

FIG. 15B is a graph illustrating a relationship between the voltage of the bit line BL input to the sense amplifier SA and the reference voltage VREF. In addition to the operation of sensing the deterioration of the memory cell MC, the sense amplifier SA may also execute a read operation of reading data recorded in the memory cell MC, and reference voltages VREF1 and VREF2 applied to each of the read operation and the operation of sensing the deterioration may differ from each other by a predetermined voltage difference (^{□}VREF).

As described above with reference to FIG. 8, in the read operation, a higher voltage may be applied to the plate line BL than the bit line BL, and the voltage of the bit line BL may be sensed to read data of the memory cell MC. For example, when the data recorded in the memory cell MC is the first data, a relatively low first data voltage VD0 may be sensed from the bit line BL, and when the data recorded in the memory cell MC is the second data, a relatively high second data voltage VD1 may be sensed from the bit line BL. In the read operation, the sense amplifier SA may read the data of the memory cell MC by comparing the voltage of the bit line BL with a first reference voltage VREF1.

Meanwhile, in the operation of sensing the deterioration, voltages having different polarities may be sequentially applied to the memory cell MC, and then, the sense amplifier SA may sense the voltage of the bit line BL and compare the sensed voltage with the reference voltage VREF. For example, in the operation of sensing the deterioration, a second program voltage for recording the second data and a first program voltage for recording the first data may be sequentially input to the memory cell MC. For example, whether the memory cell MC is deteriorated may be sensed by resetting the data of the memory cell MC to the second data and then executing the read operation.

Since the data of the memory cell MC is reset to the second data regardless of the previously recorded data, when there is no or only mild deterioration in the memory cell MC, the second data voltage VD1 may be sensed on the bit line BL. On the other hand, when there is deterioration in the memory cell MC, a deterioration voltage VD1_DEG lower than the second data voltage VD1 may be sensed on the bit line BL.

However, since both the second data voltage VD1 and the deterioration voltage VD1_DEG are higher than the first reference voltage VREF1, under the condition that the first reference voltage VREF1 is input to the sense amplifier SA, the second data voltage VD1 and the deterioration voltage VD1_DEG may not be distinguished from each other. In some implementations, in order to distinguish between the second data voltage VD1 and the deterioration voltage VD1_DEG, the reference voltage VREF input to the sense amplifier SA is increased from the first reference voltage VREF1 to the second reference voltage VREF2. Accordingly, the sensing signal SOUT may be output differently in each case in which the voltage of the bit line BL is the second data voltage VD1 and in which the voltage of the bit line BL is the deterioration voltage VD1_DEG, and the control logic may determine whether the memory cell MC is deteriorated by referring to the sensing signal SOUT.

A magnitude of the deterioration voltage VD1_DEG may vary depending on the degree of deterioration present in the memory cell MC. As described above with reference to FIG. 14A, as the deterioration of the memory cell MC becomes more severe, the difference between the positive polarization degree and the negative polarization degree may decrease, and a magnitude of the deterioration voltage VD1_DEG may also decrease. Accordingly, the second reference voltage VREF2 may be set to be high, so that the deterioration of the memory cell MC may be sensed more effectively. For example, as the second reference voltage VREF2 is made high, even small deterioration present in the memory cell MC may be sensed. According to some implementations, the control logic may execute the operation of sensing the deterioration of the memory cell MC two or more times while changing a magnitude of the second reference voltage VREF2.

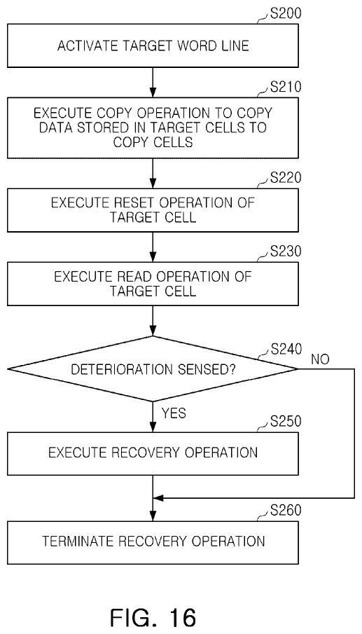

FIG. 16 is a flowchart illustrating a recovery operation of a semiconductor device according to some implementations of the present disclosure.

In some implementations, as described with reference to FIG. 16, the recovery operation for compensating for the deterioration of the memory cell is executed during the operation of the semiconductor device. The semiconductor device may first determine the target word line to which the target cells, which are targets of the recovery operation, are connected, and may activate the target word line (S200). When the target word line is activated, a copy operation to copy data of the target cells connected to the target word line to copy cells connected to a word line different from the target word line may be executed in the semiconductor device (S210).

In the recovery operation, voltages having different polarities may be sequentially input to each of the target cells, and the voltages may include a first program voltage for recording the first data and a second program voltage for recording the second data. Accordingly, since the data previously recorded in the target cells is lost by the recovery operation, in the recovery operation executed during the operation of the semiconductor device, the copy operation of transmitting the data of the target cells to the copy cells may be executed first.

When the copy operation is completed, a reset operation for the target cells may be executed (S220). In the reset operation, the first program voltage or the second program voltage may be input to the target cells. The first data may be recorded by inputting the first program voltage to the target cells, and the second data may be recorded by inputting the second program voltage, and the data of the target cells may be reset to the first data or the second data by the reset operation. When the target cells are reset, the peripheral circuit region may execute a read operation for the target cells (S230).

In the read operation, a charge sharing operation and a sensing operation for the target cells may be executed. In the charge sharing operation, a voltage of an opposite polarity to the voltage input to the target cell in the reset operation of operation S220 may be input. For example, when the second program voltage is input to the target cell in the reset operation, the first program voltage may be input in the charge sharing operation. A polarization degree of the capacitor included in the target cell may be set to a second polarization degree by the second program voltage in the reset operation, and may be set to a first polarization degree by the first program voltage in the read operation. In the sensing operation, a voltage of the capacitor corresponding to a difference between the first polarization degree and the second polarization degree may be sensed by the sense amplifiers through the target bit lines connected to the target cells.

The peripheral circuit region may determine whether the target cell is deteriorated by referring to the voltage sensed by the sense amplifiers in the read operation of operation S230 (S240). As described above with reference to FIG. 15B, the voltage of the target cell in which the deterioration has occurred may be relatively lower than the voltage of the target cell in which the deterioration has not occurred. Accordingly, the peripheral circuit region may determine that the deterioration has occurred in the target cell outputting a voltage lower than the reference voltage.

For the target cell in which the deterioration has been sensed in operation S240, the peripheral circuit region may execute a recovery operation (S250). The recovery operation may be an operation of applying a recovery voltage to the target cell in which deterioration has been sensed. Charge imbalance of the capacitor included in the target cell may be resolved by the recovery voltage. As described above with reference to FIG. 9, the recovery voltage may vary depending on the cause and type of deterioration occurring in the target cell.

When the recovery voltage is input to the target cell, a precharge operation of initializing the voltage of the target bit line connected to the target cell may be executed and the recovery operation may be terminated (S260). On the other hand, when the deterioration is not sensed in operation S140, the recovery voltage may not be input to the target cell, and the precharge operation of initializing the voltage of the target bit line may be executed and the recovery operation may be terminated.

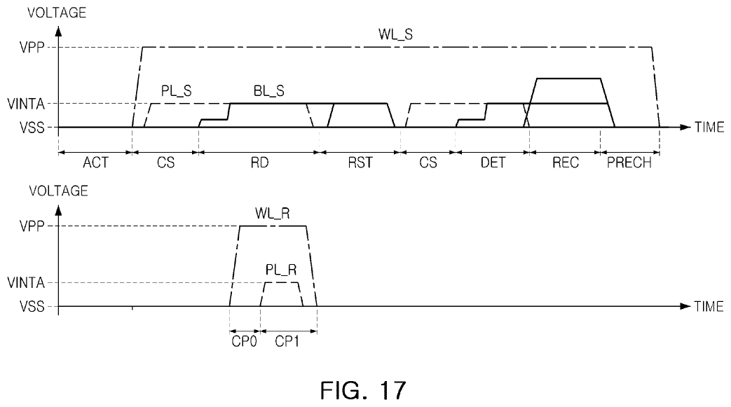

FIG. 17 is a view illustrating a recovery operation of a semiconductor device according to some implementations of the present disclosure.

The recovery operation illustrated in FIG. 17 may be executed when booting and/or during operation of the semiconductor device (e.g., after booting). In some implementations, as shown in FIG. 17, before sensing whether a target cell is deteriorated in the recovery operation, a copy operation to copy data of the target cell to a copy cell may be executed first. In order to execute the copy operation, the target cell and the copy cell may be connected to different word lines WL_S and WL_R and plate lines PL_S and PL_R. A bit line BL_S may be shared by the target cell and the copy cell, or the target cell and the copy cell may be connected to different bit lines.

Referring to FIG. 17, in the activation section ACT, a turn-on voltage VPP may be input to the target word line WL_S connected to the target cell, and the target cell may be activated by the turn-on voltage. Then, in the charge sharing section CS, while a voltage of the target bit line BL_S is maintained at the first voltage VSS, a voltage of the target plate line PL_S may be increased to the second voltage VINTA, and a polarization degree of the capacitor included in the target cell may be set to a negative polarization degree.

In the subsequent sensing section RD, the sense amplifier SA connected to the target bit line BL_S may read data of the target cell. For example, when the voltage of the target bit line BL_S is lower than the reference voltage, the data of the target cell may be read as the first data, and when the voltage of the target bit line BL_S is higher than the reference voltage, the data of the target cell may be read as the second data. The reference voltage input to the sense amplifier in the sensing section RD may be the first reference voltage VREF1 described above with reference to FIG. 15B.

In the sensing section RD, the copy word line WL_R different from the target word line WL_S may be activated by the turn-on voltage VPP. In some implementations, the copy word line WL_R is also be activated in the charge sharing section CS. When the copy word line WL_R connected to the copy cell is activated, a voltage of the copy plate line PL_R connected to the copy cell may be maintained at the first voltage VSS during a first copy time CP0, and then, the voltage of the copy plate line PL_R may be set to the second voltage VINTA during a second copy time CP1.

When the data of the target cell sensed in the sensing section RD is the first data, the voltage of the target bit line BL_S may be maintained at the first voltage VSS during the sensing section RD. Accordingly, during the first copy time CP0 at which the first voltage VSS is applied to the copy plate line PL_R, the program operation may not be executed in the copy cell, and during the second copy time CP1 at which the second voltage VINTA is applied to the copy plate line PL_R, the first data may be recorded in the copy cell.

Meanwhile, when the data of the target cell detected in the sensing section RD is the second data, the voltage of the target bit line BL_S may be increased to the second voltage VINTA during the sensing section RD. Accordingly, the second data may be recorded in the copy cell during the first copy time CP0 at which the first voltage VSS is applied to the copy plate line PL_R, and the program operation may not be executed in the copy cell during the second copy time CP1 at which the second voltage VINTA is applied to the copy plate line PL_R. Accordingly, as illustrated in FIG. 17, the copy operation to copy the data recorded in the target cell to the copy cell may be executed by controlling the voltage of the copy plate line PL_R.

When the copy operation and the sensing operation RD are terminated, a reset operation of resetting the data of the target cell may be executed during the reset section RST. Then, by operations in each of the charge sharing section CS, the detection section DET, the recovery section REC and the precharge section PRECH, the deterioration of the target cell may be sensed and the recovery operation may be executed accordingly. The operations during the reset section RST, the charge sharing section CS, the detection section DET, the recovery section REC and the precharge section PRECH may be similar to those described above with reference to FIG. 10. For example, the reference voltage input to the sense amplifier in the detection section DET may be the second reference voltage VREF2 that is higher than the first reference voltage VREF1, as described above with reference to FIG. 15B.

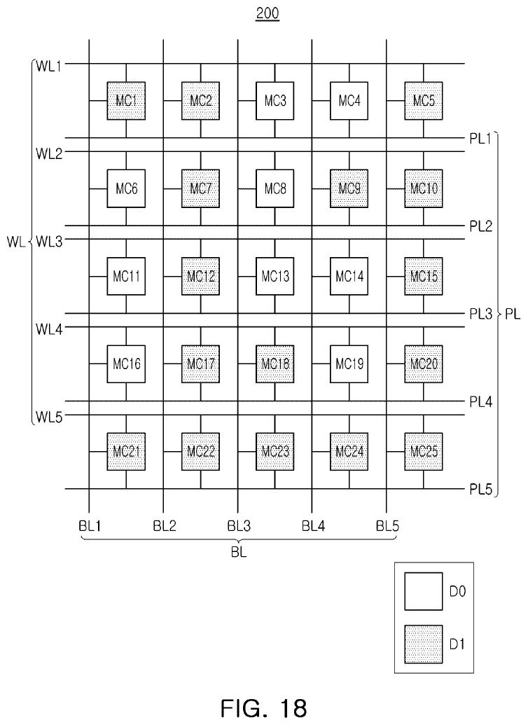

FIGS. 18 to 20 are views illustrating a recovery operation of a semiconductor device according to some implementations of the present disclosure.

FIGS. 18 to 20 are views illustrating a copy operation to copy data of a target cell to a copy cell prior to a degradation sensing and recovery operation for the target cell. A semiconductor device 200 described with reference to FIGS. 18 to 20 may include a plurality of memory cells MC1 to MC25, and the plurality of memory cells MC1 to MC25 may be connected to a plurality of word lines WL1 to WL5 (WL), a plurality of plate lines PL1 to PL5 (PL), and a plurality of bit lines BL1 to BL5 (BL).

Each of the plurality of memory cells MC1 to MC25 may have a first program state in which first data D0 is recorded or a second program state in which second data D1 is recorded. The program state of the plurality of memory cells MC1 to MC25 may be determined by voltages applied to the plurality of plate lines PL and the plurality of bit lines BL.

FIG. 18 is a view illustrating the program states of each of the plurality of memory cells MC1 to MC25 at a time immediately before the start of the recovery operation in the semiconductor device 200. For example, the semiconductor device 200 may execute the recovery operation when the semiconductor device 200 is not in use, or under a condition in which a system including the semiconductor device 200 enters a standby state or the like.

In a case where the first word line WL1 is a target word line of the recovery operation, the semiconductor device 200 may first copy the data of the first to fifth memory cells MC1 to MC5 connected to the first word line WL1 to other memory cells MC6 to MC25. As described above with reference to FIG. 17, in order to read the data of the first to fifth memory cells MC1 to MC5, the first word line WL1 may be activated, a first voltage VSS may be applied to the first bit line BL1, and a second voltage VINTA may be applied to the first plate line PL1.

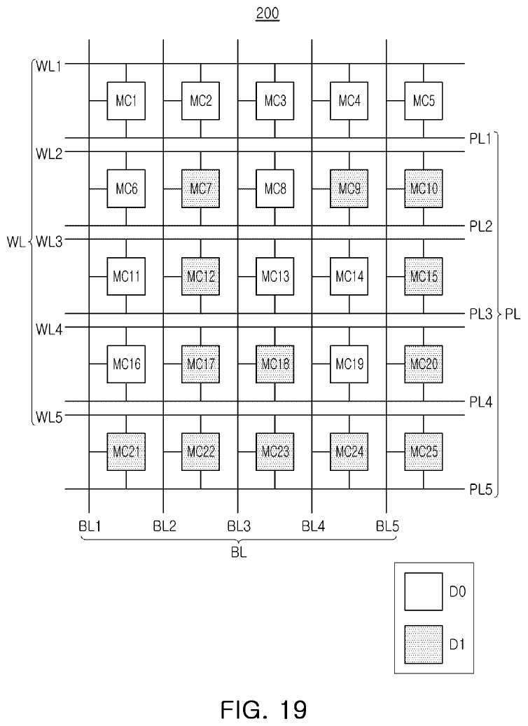

Accordingly, as illustrated in FIG. 19, the first data D0 may be recorded in the first to fifth memory cells MC1 to MC5, and the voltages of each of the first to fifth bit lines BL1 to BL5 may vary depending on the data recorded in each of the first to fifth memory cells MC1 to MC5 at the time illustrated in FIG. 18. For example, the voltage of the third and fourth bit lines BL3 and BL4 connected to the third and fourth memory cells MC3 and MC4 in which the first data D0 has been recorded may be set to the first voltage VSS. On the other hand, the voltage of the first, second and fifth bit lines BL1, BL2 and BL5 connected to the first, second and fifth memory cells MC1, MC2 and MC5 in which the second data D1 has been recorded may be increased to the second voltage VINTA.

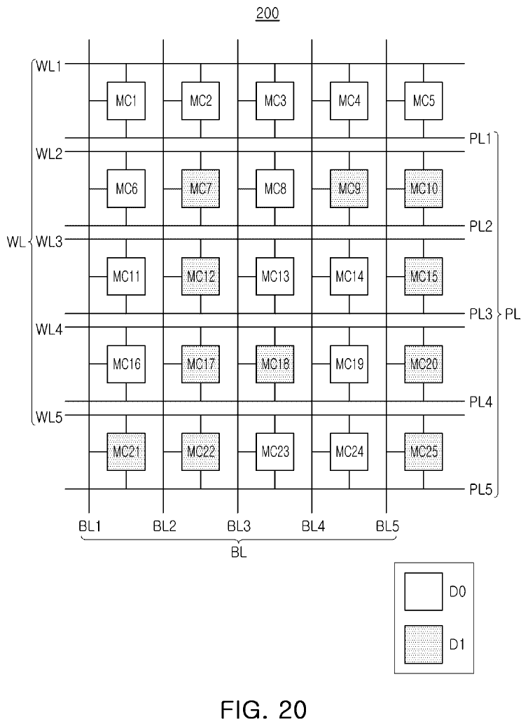

Next, as illustrated in FIG. 20, data of the first to fifth memory cells MC1 to MC5 may be copied to the memory cells MC21 to MC25 connected to the fifth word line WL5, which is a copy word line. Data of the first memory cell MC1 may be copied to the twenty-first memory cell MC21, data of the second memory cell MC2 may be copied to the twenty-second memory cell MC22, and data of the third memory cell MC3 may be copied to the twenty-third memory cell MC23. Additionally, data of the fourth memory cell MC4 may be copied to the twenty-fourth memory cell MC24, and data of the fifth memory cell MC5 may be copied to the twenty-fifth memory cell MC25. As described above with reference to FIG. 17, the data of the first, second and fifth memory cells MC1, MC2 and MC5 may be copied during the first copy time CP0 in which the voltage of the fifth plate line PL5 is maintained at the first voltage VSS, and the data of the third and fourth memory cells MC3 and MC4 may be copied during the second copy time CP1 in which the voltage of the fifth plate line PL5 is set to the second voltage VINTA.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been illustrated and described above, it will be apparent to those skilled in the art that modifications and variations could be made without departing from the scope of the present disclosure.

What is claimed is:

1. A semiconductor device, comprising:
a cell region comprising a plurality of memory cells connected to a plurality of word lines, a plurality of bit lines, and a plurality of plate lines,
wherein each of the plurality of memory cells comprises a switch element and at least one capacitor connected to the switch element, wherein each capacitor of the at least one capacitor includes a ferroelectric layer; and
a peripheral circuit region comprising peripheral circuitry configured to control the plurality of memory cells using the plurality of word lines, the plurality of bit lines, and the plurality of plate lines,
wherein the peripheral circuitry is configured to, in a recovery operation:
turn on a switch element included in a target cell, among the plurality of memory cells, to activate the target cell, and
while the target cell is activated:
input a first voltage to a target plate line connected to the target cell and input a second voltage, higher than the first voltage, to a target bit line connected to the target cell,
subsequent to inputting the first voltage to the target plate line and inputting the second voltage to the target bit line, input the second voltage to the target plate line and input the first voltage to the target bit line, and
based on a voltage of the target bit line being lower than a predetermined reference voltage, increase the voltage of the target bit line to a third voltage, higher than the second voltage.

2. The semiconductor device of claim 1, wherein the peripheral circuitry comprises:
a word line driving circuit including word line drivers connected to the plurality of word lines;
a sense amplifier circuit including sense amplifiers connected to the plurality of bit lines; and
a plate line driving circuit including plate line drivers connected to the plurality of plate lines.

3. The semiconductor device of claim 1, wherein the peripheral circuitry is configured to maintain the voltage of the target bit line at the second voltage based on the voltage of the target bit line being higher than the predetermined reference voltage.

4. The semiconductor device of claim 1, wherein the peripheral circuitry is configured to reduce the voltage of the target bit line to the first voltage a predetermined time after the voltage of the target bit line is sensed to be lower than the predetermined reference voltage.

5. The semiconductor device of claim 1, wherein the peripheral circuitry is configured to turn on the switch element of the target cell by applying a turn-on voltage to the switch element of the target cell, and
wherein the turn-on voltage is higher than the third voltage.

6. The semiconductor device of claim 1, wherein the target cell is configured to reset stored data in response to receiving the first voltage from the target plate line and second voltage from the target bit line.

7. The semiconductor device of claim 6, wherein the peripheral circuitry is configured to copy data of the target cell to a copy cell prior to inputting the first voltage to the target plate line and inputting the second voltage to the target bit line.

8. The semiconductor device of claim 7, wherein the target cell and the copy cell share the target bit line, and
wherein the copy cell is connected to:
a copy word line different from a target word line to which the target cell is connected, and
a copy plate line different from the target plate line.

9. The semiconductor device of claim 8, wherein the peripheral circuitry is configured to copy the data of the target cell by:
inputting the second voltage to the target plate line to read the data of the target cell, and
while the second voltage is input to the target plate line:
turning on a switch element included in the copy cell using the copy word line, and
inputting the first voltage to the copy plate line during a first copy time and inputting the second voltage to the copy plate line during a second copy time subsequent to the first copy time.

10. The semiconductor device of claim 9, wherein the peripheral circuitry is configured to read the data of the target cell by comparing the voltage of the target bit line to a first reference voltage less than the predetermined reference voltage.

11. The semiconductor device of claim 1, wherein each of the plurality of memory cells includes the switch element and a plurality of capacitors connected to the switch element, and
wherein, in each of the plurality of memory cells, the plurality of capacitors of the memory cells are connected to different plate lines.

12. The semiconductor device of claim 11, wherein, in each of the memory cells, the switch element of the memory cell is connected to one of the word lines and one of the bit lines.

13. The semiconductor device of claim 1, wherein, in a program operation for a selected memory cell among the plurality of memory cells, the peripheral circuit region is configured to input a first program voltage to the selected memory cell to record first data, and to input a second program voltage, having an opposite polarity to the first program voltage, to the selected memory cell to record second data, and
wherein the third voltage is higher than the first program voltage and the second program voltage.

14. The semiconductor device of claim 13, wherein a polarity of the third voltage matches a polarity of the second program voltage.

15. A semiconductor device, comprising:
a cell region including a plurality of memory cells connected to a plurality of word lines, a plurality of plate lines, and a plurality of bit lines; and
a peripheral circuit region comprising peripheral circuitry configured to control the plurality of memory cells,
wherein the peripheral circuitry is configured to, in a recovery operation:
apply a first program voltage and a second program voltage having different polarities across a target cell among the plurality of memory cells,
compare a voltage of a target bit line connected to the target cell to a predetermined reference voltage, and
input a recovery voltage, higher than the first program voltage and the second program voltage, to the target cell based on the comparison of the voltage of the target bit line to the predetermined reference voltage.

16. The semiconductor device of claim 15, wherein the target cell comprises a switch element and at least one capacitor connected to the switch element, wherein each capacitor of the at least one capacitor comprises a ferroelectric layer.

17. The semiconductor device of claim 16, wherein the ferroelectric layer in each capacitor of the at least one capacitor is configured to be set to a first polarization degree by the first program voltage and a second polarization degree different from the first polarization degree by the second program voltage, and
wherein the voltage of the target bit line is based on a difference between the first polarization degree and the second polarization degree.

18. The semiconductor device of claim 15, wherein the peripheral circuitry is configured to input the recovery voltage to the target bit line.

19. A semiconductor device, comprising:
a cell region including a plurality of memory cells connected to a plurality of word lines, a plurality of plate lines, and a plurality of bit lines; and
a peripheral circuit region comprising peripheral circuitry configured to change a degree of polarization of the plurality of memory cells to record first data or second data in the plurality of memory cells, and
wherein the peripheral circuitry is configured to, in a recovery operation:
input a reset voltage to a target cell among the plurality of memory cells to reset data of the target cell to the second data,
execute a read operation for the target cell to sense deterioration of the target cell, and
input a recovery voltage, higher than the reset voltage, to the target cell based on sensing the deterioration of the target cell.

20. The semiconductor device of claim 19, wherein the peripheral circuitry is configured to execute the read operation by:
changing the data of the target cell to the first data, and
comparing a voltage of a target bit line connected to the target cell to a predetermined reference voltage.
